(19) United States
(12) Patent Application Publication
(10) Pub. No.: US 2013/0152995 A1
(43) Pub. Date: Jun. 20, 2013

(54) SOLAR CELL MODULE AND METHOD FOR PRODUCING THE SAME

(71) Applicant: PANASONIC CORPORARION, Osaka (JP)

(72) Inventors: MICHIRU KUROMIYA, Osaka (JP); TOMOHIRO OKUMURA, Osaka (JP)

(73) Assignee: PANASONIC CORPORARION, Osaka (JP)

(21) Appl. No.: 13/713,105

(22) Filed: Dec. 13, 2012

(30) Foreign Application Priority Data
Dec. 14, 2011 (JP) 2011-272859

(51) Int. Cl. H01L 31/0216; H01L 31/18

(52) U.S. Cl. CPC H01L 31/02168; H01L 31/18
USPC 136/244; 136/256; 438/65

(57) ABSTRACT

A solar cell module which not only can ensure that rays of light in a satisfactory amount enter the solar cells but also can suppress the deterioration of the antireflection film in reflectance to surely achieve excellent durability. By forming, on the surface of a first antireflection film, a second antireflection film having a void ratio smaller than that of the first antireflection film, CO₂ and H₂O in air are prevented from permeating through the antireflection film, so that a reaction of CO₂ and H₂O with alkali ions on the surface of a light-transmitting member is unlikely to proceed, making it possible to cause rays of light in a satisfactory amount to surely enter the solar cells and to suppress the deterioration of the antireflection film in reflectance to surely achieve excellent durability.

### CROSS REFERENCE TO RELATED APPLICATIONS

This application is entitled and claims the benefit of Japanese Patent Application No. 2011-272859, filed on Dec. 14, 2011, the disclosure of which including the specification, drawings and abstract is incorporated herein by reference in its entirety.

### BACKGROUND

1. Technical Field

The technical field relates to a solar cell. More particularly, the present technical field is concerned with a solar cell module comprising solar cells each having an antireflection film, and a method for producing the same.

2. Background Art

In recent years, a solar cell has attracted attention as a source of clean energy. Particularly, a silicon solar cell having high efficiency of power generation is attracting much attention because it is promising high-end electric power for use in houses and the like, and the improvement of the exchange efficiency and the reduction of the cost of the silicon solar cell and the like are vigorously studied.

Especially, with respect to a solar cell module, a method has been known in which an antireflection film is formed on a light-transmitting member and the reflectance is reduced utilizing a difference in refractive index between the light-transmitting member and the antireflection film. In this method, the antireflection film prevents rays of sunlight from being reflected off the light-transmitting member, enabling a larger amount of the rays of sunlight to enter the photoelectric transfer region of the solar cell. As a method for forming the antireflection film, there is a sol-gel method. Specifically, there has been proposed a sol-gel method in which a metal alkoxide and an organic solvent are mixed with each other, and the resultant mixture is subjected to hydrolysis using water and a catalyst to obtain a hydroxide, and the hydroxide as a reaction product is subjected to condensation to form a metal oxide (see, for example, JP-A-2003-201443).

Si(OR)₄+4H₂0→Si(OH)₄+4ROH

Si(OH)₄→SiO₂+2H₂0

The antireflection film formed by a sol-gel method is a porous film having silica particles and a matrix holding the silica particles. The void portion in the porous antireflection film has a refractive index substantially the same as that of air (refractive index: 1.0) and hence, even when the material for the fine particles or the matrix holding the particles in the antireflection film has a larger refractive index, the antireflection film collectively has a refractive index close to that of air. Therefore, by forming the antireflection film on the light-transmitting member, the reflectance can be reduced.
Patent document 2: JP-A-2004-131314

Generally, the antireflection film formed on the light-transmitting member of the solar cell module is allowed to stand outdoors for a long term, and the antireflection film once fitted is difficult to exchange. For this reason, the antireflection film is required to have high physical and chemical durability and high stain-resistance. However, in the light-transmitting member having an antireflection film formed using a sol-gel method, a problem arises in that satisfactory physical and chemical durability and stain-resistance cannot be obtained, so that the light transmission is lowered when the film is allowed to stand for a long term.

For example, with respect to a solar cell using, as a light-transmitting member, a glass substrate containing an alkali element, it is known that when the solar cell is exposed to air, the surface of glass deteriorates due to the humidity in air {see, for example, Technical Materials of Nippon Sheet Glass Co., Ltd., NTR News No. 30 (published on Apr. 1, 2006)}. The mechanism of the deterioration of the surface of glass is described below. Na⁺ ions contained in the glass are first diffused on the surface of the glass, and the Na⁺ ions and H₂O in air adsorbing on the surface of the glass together form a large tetrahydrate, and thus the Na⁺ ions cannot go back into the glass, so that H⁺ ions go into the glass to balance the charges.

Na⁺(Glass)+H₂O→NaOH+H⁺(Into glass)

Then, the Na hydrate reacts with CO₂ in air to form a carbonate, and thus a carbonate nucleus is formed on the surface of the glass.

2NaOH+CO₂(Air)→Na₂CO₃+H₂O

Na₂CO₃+CO₂(Air)+H₂O→2NaHCO₃

The formed carbonate has a deliquescent property. Therefore, the carbonate then incorporates thereinto H₂O in air to become larger, and further is neutralized with CO₂ in air to cause crystallization or grain growth, so that the resultant crystals or grains cover the surface of the glass. Furthermore, NaOH and Na₂CO₃, which are formed at the initial stages in the above reactions, have a deliquescent property, and therefore form a solution having a pH of 12 or more to fuse the glass per se, forming an uneven surface in the glass.

As mentioned above, the antireflection film formed using a sol-gel method is porous, and therefore H₂O and CO₂ in air permeate through the voids of the antireflection film and reach the surface of the light-transmitting member and react with Na⁺ ions present on the surface of the light-transmitting member. As a result, the formation of crystals on the surface of the light-transmitting member or the dissolution of the surface of the light-transmitting member occurs or causes peeling at the interface between the light-transmitting member and the antireflection film or a crack in the antireflection layer, leading to the lowering of the light transmission when stored for a long term. Further, the antireflection layer is porous and hence, particularly in wet weather, water and dust permeate through the voids of the antireflection layer to increase the refractive index, causing the lowering of the light transmission when stored for a long term.

### SUMMARY

In view of the above-mentioned problems, an object is to provide a solar cell module which not only can ensure that rays of light in a satisfactory amount enter the solar cells but also can suppress the deterioration of the antireflection film in reflectance to surely achieve excellent durability.

For achieving the above object, the solar cell module comprises a plurality of solar cells; a connector for electrically connecting the adjacent solar cells to each other; a light-transmitting member disposed so as to cover a light receiving surface of the solar cell module and containing an alkali element; a first antireflection film formed on the light-transmitting member and comprising silica, a siloxane, and voids of the silica; and a second antireflection film formed on the surface of the first antireflection film and comprising the silica and the siloxane, wherein the silica has a particle diameter of 5 to 50 nm.

Further, the method for producing a solar cell module comprises: forming a light-transmitting member containing an alkali element on light receiving surfaces of a plurality of solar cells; subjecting a mixture of polysiloxane, silica particles, and an organic solvent to drying and firing to form an antireflection film precursor on the light-transmitting member; subjecting the antireflection film precursor to thermodrying to form a first antireflection film comprising silica, a siloxane, and voids of the silica; and subjecting the surface of the first antireflection film to rapid heat treatment so that the silica particles are fused to form a second antireflection film containing the silica and the siloxane, wherein the silica has a particle diameter of 5 to 50 nm.

By virtue of having the above-mentioned construction, the solar cell module is advantageous not only in that rays of light in a satisfactory amount surely enter the solar cells, but also in that the deterioration of the antireflection film in reflectance can be suppressed to surely achieve excellent durability.

### BRIEF DESCRIPTION OF THE DRAWINGS

FIG. 1 is a cross-sectional view showing the structure of the solar cell.

FIG. 2 is a cross-sectional view showing the structure of the solar cell module.

FIG. 3 is a diagrammatic explanatory view showing the structure of the antireflection film.

FIGS. 4A to 4C are cross-sectional views explaining the steps in the method for forming the antireflection film.

### DESCRIPTION OF REFERENCE NUMERALS

1: Solar cell
2: Connector
3: Light-transmitting sealant
4: Antireflection film
4a: First antireflection film
4b: Second antireflection film
5: Light-transmitting member
6: Back surface member
7: Frame member
8: Voids
9: Silica particles
11: Crystalline silicon substrate
12: n-Type layer
13: Antireflection film
14: Light receiving surface electrode
15: p-Type layer
16: Back surface electrode
17: Heat source for rapid heat treatment
24: Antireflection film precursor

### DETAILED DESCRIPTION

Hereinbelow, an exemplary embodiment will be described with reference to the accompanying drawings.

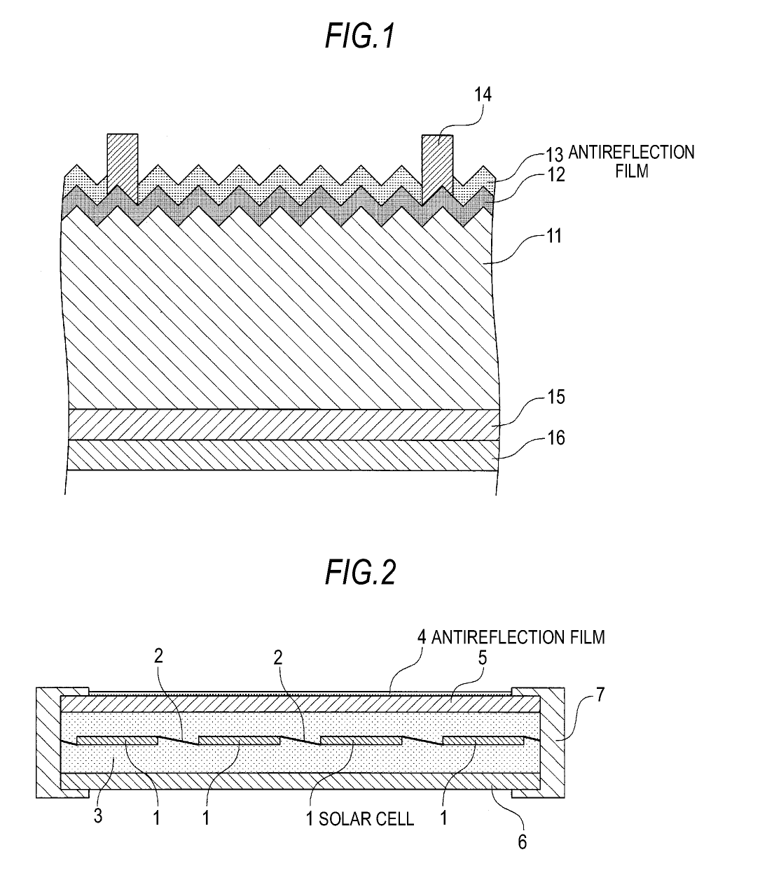

The constructions of the solar cell and the solar cell module are first described with reference to FIGS. 1 to 3.

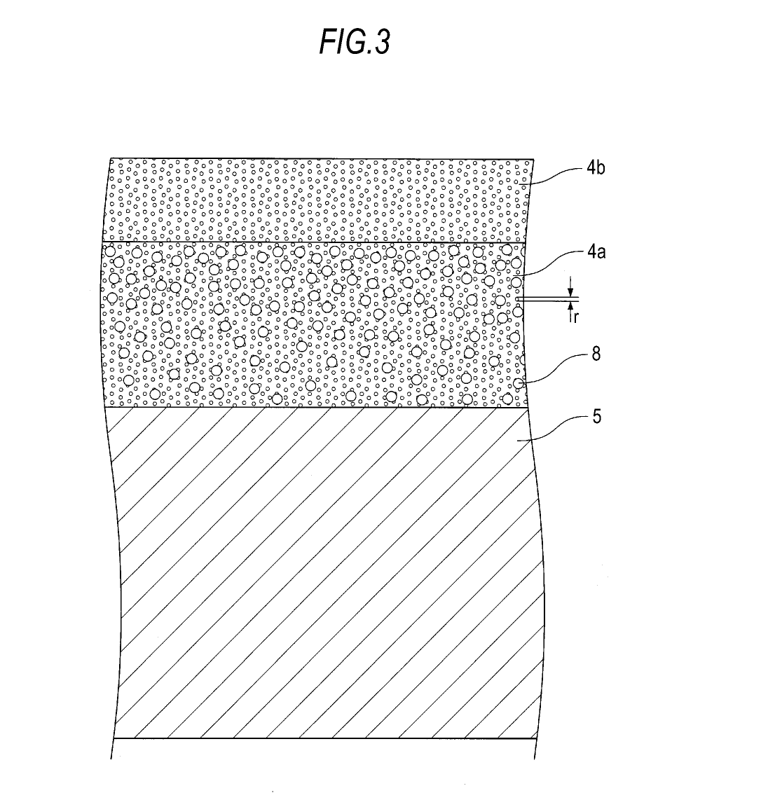

FIG. 1 is a cross-sectional view showing the structure of the solar cell, FIG. 2 is a cross-sectional view showing the structure of the solar cell module, and FIG. 3 is a diagrammatic explanatory view showing the structure of the antireflection film.

In the solar cell shown in FIG. 1, reference numeral 11 designates a crystalline silicon substrate, and an n-type layer 12 and an antireflection film 13 are stacked in this order on the light receiving surface side of the crystalline silicon substrate 11. In FIG. 1, reference numeral 14 designates a light receiving surface electrode formed by firing on the n-type layer 12, and the surface of the light receiving surface electrode is exposed through the antireflection film 13. Further, a highly doped p-type layer 15, which is doped with a p-type impurity at a high concentration, and a back surface electrode 16 are stacked on the back surface side of the crystalline silicon substrate 11.

In FIGS. 2 and 3, reference numeral 1 designates a plurality of solar cells, and each of the solar cells corresponds to the solar cell shown in FIG. 1. In the adjacent solar cells 1, alight receiving surface electrode (not shown) of one of them and a back surface electrode (not shown) of another one are electrically connected to each other by a connector 2, and thus the solar cells are electrically connected in series. On the light receiving surface side of the solar cells 1, a light-transmitting member 5 formed from glass, a plastic, or the like is disposed through a light-transmitting sealant 3 such as, for example, EVA. On the back surface side of the solar cells 1, aback surface member 6 having a resin such as, for example, Tedlar, stacked on an aluminum foil is disposed through a light-transmitting sealant 3 such as, for example, EVA. The solar cells 1 and the light-transmitting member 5 as well as the light-transmitting sealant 3 are unified by a frame member 7 formed from aluminum.

An antireflection film 4 is formed on the back surface side of the light-transmitting member 5 opposite to the solar cells 1. The antireflection film 4 comprises a first antireflection film 4a and a second antireflection film 4b formed on the first antireflection film 4a. The light-transmitting member 5 may be directly formed on the light receiving surface of the solar cells 1 without forming the light-transmitting sealant 3.

The antireflection film 4 of the solar cell module, particularly the first antireflection film 4a has formed therein voids 8. The first antireflection film 4a has a function of suppressing the reflection of light to ensure that rays of light in a satisfactory amount enter the solar cells 1. Air has a refractive index of 1.0, and the light-transmitting member 5 formed from glass or the like generally has a refractive index of about 1.5. The voids 8 can be considered to be layers of air, and therefore the refractive index of the voids 8 is 1.0. The refractive index of the first antireflection film 4a is determined by the amount of the voids 8. For obtaining an antireflection effect from the first antireflection film 4a, it is preferred that the refractive index of the first antireflection film 4a is gradually reduced in the direction of from the interface between the first antireflection film 4a and the light-transmitting member 5 toward the interface between the first antireflection film 4a and air. Therefore, the first antireflection film 4a is formed so that the amount of the voids 8 is gradually increased in the direction of from the interface between the first antireflection film 4a and the light-transmitting member 5 toward the interface between the first antireflection film 4a and air to reduce the reflectance, increasing the amount of rays of light entering the solar cells 1.

The antireflection film 4 is formed by a sol-gel method, and comprises silica particles 9 bonded to a siloxane and the voids 8 which are gaps between the regions in which the silica particles bonded to the siloxane are formed. When the silica particles 9 have a particle diameter r of 5 to 50 nm, both the light transmission properties and durability of the antireflection film can be achieved. Particularly, with respect to the antireflection film 4 for use in the solar cell module, it is important that the light transmission is increased, and hence it is desired that the particle diameter r of the silica particles 9 is as small as possible. However, for surely obtaining the required minimum durability of the antireflection film, the silica particles 9 are needed to have a particle diameter r of about 5 nm. Further, it is preferred that the antireflection film 4 has a thickness of 100 to 200 nm.

On the back surface of the antireflection film 4 opposite to the surface in contact with the light-transmitting member 5, a thin second antireflection film 4b is formed by subjecting the antireflection film 4 to rapid heat treatment. The second antireflection film 4b is formed by a heat treatment which nullifies or reduces the voids 8 of the antireflection film 4. The large voids 8 cause H₂O and CO₂ to pass through the antireflection film 4, so that H₂O and CO₂ react with an alkali element contained in the light-transmitting member 5, leading to the deterioration of the light-transmitting member 5. In the embodiment, by virtue of the second antireflection film 4b having the voids reduced, H₂O and CO₂ are prevented from passing through the antireflection film 4 to avoid the deterioration of the light-transmitting member 5, making it possible to prevent the occurrence of peeling at the interface between the light-transmitting member 5 and the antireflection film 4, the formation of a crack in the antireflection film 4, or the lowering of the light transmission when stored for a long term. Particularly, in a glass substrate used in a plasma display panel and the like, for obtaining a dielectric strength, the alkali content is reduced, but, in the glass substrate used in the light-transmitting member 5 for solar cell, the alkali content is increased, and the effect of preventing the lowering of the light transmission when stored for a long term, obtained by suppression of the permeation of gas or the like by the second antireflection film 4b is remarkable.

Taking into consideration the effect on the optical properties of the antireflection film, it is preferred that the thickness of the second antireflection film 4b is 10% or less of the thickness of the antireflection film 4. In other words, the thickness of the second antireflection film 4b is 1/10 or less of the light wavelength/refractive index. A ray of sunlight has a wavelength in the range of 300 nm or more, and the second antireflection film 4b has a refractive index of about 1.33. Therefore, the thickness of the second antireflection film 4b is 300/1.33×10%=22.5 nm or less. As mentioned above, the thickness of the antireflection film 4 is preferably 100 to 200 nm, and therefore, it is preferred that the thickness of the second antireflection film 4b is about 10% or less of the thickness of the antireflection film 4. In the embodiment, the voids 8 of the second antireflection film 4b are reduced, and the silica particles 9 have a particle diameter r as very small as 5 to 50 nm, and therefore permeation of gas or the like through the antireflection film can be suppressed.

The antireflection film 4 formed by a sol-gel method comprises the silica particles 9 and a siloxane (not shown) connecting the silica particles 9 to one another. In the embodiment, with respect to the ratio between the amounts of the silica and the siloxane contained in the antireflection film 4, it is preferred that the silica:siloxane ratio is 80:20 to 95:5. In a general silica film formed by a sol-gel method, when the amount of a siloxane having an alkyl group in the side chain is increased, a large amount of CH₃ may be generated due to the remaining alkyl group after firing to cause the deterioration of the material formed surrounding the silica film. Therefore, the amount of the siloxane contained in the silica film is reduced to increase the silica ratio. In contrast, in the antireflection film 4 in the embodiment, for preventing the transmission of light from being inhibited by the silica particles 9, the silica ratio is preferably set lower than usual.

Generally, in the antireflection film 4, a phase difference between the light reflected off the interface between the antireflection film 4 and the light-transmitting member 5 and the light reflected off the surface of the antireflection film 4 is ½ of the wavelength of the incident light, and thus the above reflected lights are offset by each other, reducing the reflection of light. When the refractive index of the antireflection film is taken as n, the thickness of the antireflection film is taken as d, and the wavelength presumed as an average wavelength of rays of light incident on the solar cells is taken as λ, the relationship between them can be represented by the formula: 2nd=λ/2. In the antireflection film 4 in the embodiment, it is preferred that the thickness of the antireflection film 4 is controlled by applying to the above formula the refractive index n which is an average refractive index of the whole of the antireflection film 4 determined by the amount of the voids 8.

Next, an example of the method for producing a solar cell module of the embodiment is described with reference to FIGS. 1 to 4.

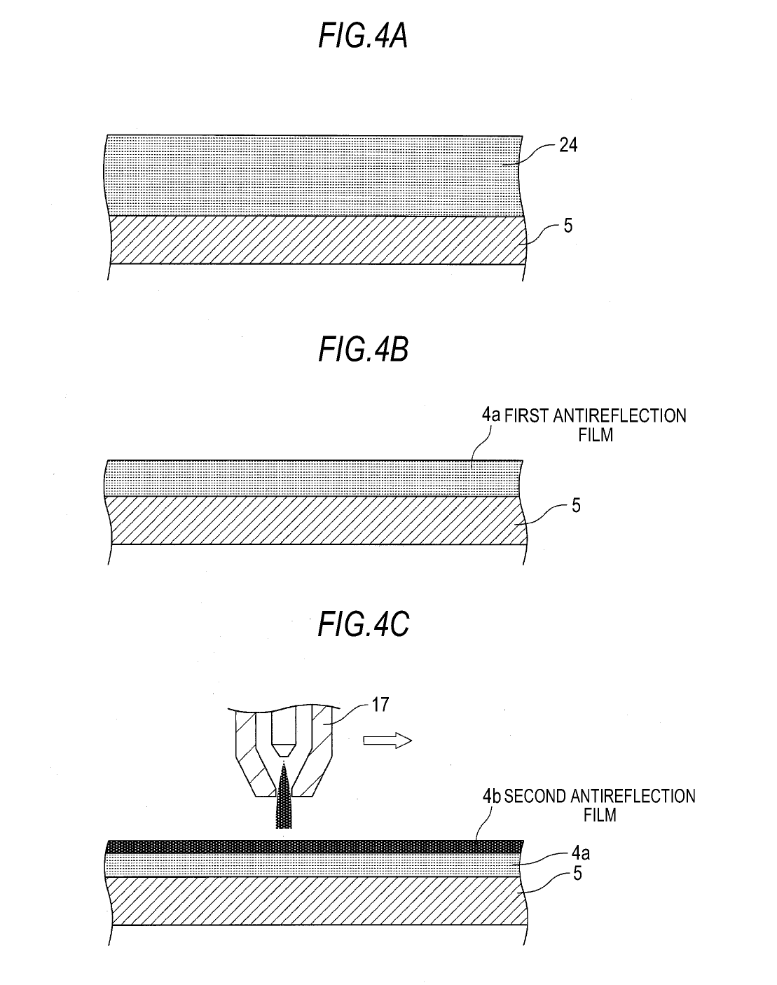

FIGS. 4A to 4C are cross-sectional views depicting the steps in the method for forming the antireflection film in the embodiment.

An example of the step for producing a solar cell is first described.

First, a textured structure for reducing the reflection of light is formed using an alkaline solution on the surface of a p-type single-crystal silicon substrate 11 having a resistivity of 1 Ω·cm and a thickness of about 350 μm. With respect to the p-type single-crystal silicon substrate 11, instead of the single-crystal silicon substrate, a crystalline silicon substrate, such as a polycrystalline silicon substrate, can be used. When a polycrystalline silicon substrate is used, a textured structure is formed using an acid solution.

Then, in a region of the light receiving surface of the single-crystal silicon substrate 11 at a depth of about 1 μm or less, thermal diffusion of phosphorus (P) is caused using POCl₃ gas at a temperature of about 900° C. to form an n-type layer 12. Instead of the POCl₃ gas, phosphorus glass (PSG) may be used. Then, an antireflection film 13 formed from SiNₓ is formed on the n-type layer 12 by a plasma CVD method. Subsequently, on the back surface of the p-type single-crystal silicon substrate 11, a back surface electrode 16 is formed by screen printing using an Al paste. Then, the resultant substrate is subjected to short-time treatment at a temperature of about 700° C. so that Al undergoes thermal diffusion through the p-type single-crystal silicon substrate 11, thus forming a p-type layer 15 highly doped with Al. Further, a light receiving surface electrode 14 is formed by printing an Ag electrode in a finger form on the antireflection film 13 formed from SiNₓ and subjecting the Ag electrode to heat treatment and a treatment called “fire through” so that Ag penetrates SiNₓ which constitutes the antireflection film 13 and the Ag is brought into contact with the surface of the n-type layer 12. Thus, a solar cell is completed.

The solar cell produced through the above-described step is sandwiched between a back surface member 6 having a Tedlar resin stacked on an aluminum foil and a light-transmitting member 5 having an antireflection film 4 formed thereon through a light-transmitting sealant 3 such as, for example, EVA, and they are unified by a frame member 7 formed from aluminum. The solar cell module shown in FIG. 2 is completed through this step. The method for producing the solar cell is not limited to the above-mentioned method, and the solar cell used in the solar cell module can be produced by an arbitrary method.

A method for forming the antireflection film 4 on the light-transmitting member 5 is described below in detail with reference to FIGS. 4A to 4C.

As shown in FIG. 4A, an antireflection film precursor which is a silicon alkoxide is first formed on the light-transmitting member 5. A raw material for the antireflection film precursor 24 comprises polysiloxane having a siloxane bond (—Si—O—), silica particles, and an organic solvent. The siloxane bond is formed by mixing a silicon alkoxide as a precursor with another organic solvent and adding to the resultant mixture water and a catalyst portion by portion while stirring at room temperature or at a higher temperature to cause a hydrolysis and a condensation polymerization.

With respect to the organic solvent with which the silicon alkoxide is mixed, there is no particular limitation as long as it can sufficiently dissolve the silicon alkoxide. For example, one type or two or more types of organic solvents are selected from alcohols including methanol, ethanol, 1-propanol, 2-propanol, hexanol, and cyclohexanol, glycols including ethylene glycol and propylene glycol, ketones including methyl ethyl ketone, diethyl ketone, and methyl isobutyl ketone, terpenes including α-terpineol, β-terpineol, and γ-terpineol, ethylene glycol monoalkyl ethers, ethylene glycol dialkyl ethers, diethylene glycol monoalkyl ethers, diethylene glycol dialkyl ethers, ethylene glycol monoalkyl ether acetates, ethylene glycol dialkyl ether acetates, diethylene glycol monoalkyl ether acetates, diethylene glycol dialkyl ether acetates, propylene glycol monoalkyl ethers, propylene glycol dialkyl ethers, propylene glycol monoalkyl ether acetates, propylene glycol dialkyl ether acetates, and monoalkylcellosolves. The use of two or more types of solvents selected causes the drying rate to be reduced, making it possible to prevent the formation of a crater on the surface of the antireflection film.

The antireflection film precursor 24 as a product is in the form of a sol of polysiloxane having a siloxane bond. With respect to the molecular weight of the formed polysiloxane, there is no particular limitation, but the polysiloxane having a higher molecular weight can be further reduced in shrinkage, improving the crack resistance. Further, the polysiloxane preferably contains an alkyl group in the structure thereof because the shrinkage due to a reaction can be blocked, improving the crack resistance. With respect to the material forming a precursor, there is no particular limitation as long as the material has a siloxane bond. For example, the precursor material may be at least one precursor material selected from the group consisting of completely inorganic polysiloxane which does not contain an alkyl group, such as methyl silicate or ethyl silicate, methyltrimethoxysilane, methyltriethoxysilane, methyltriisopropoxysilane, ethyltrimethoxysilane, ethyltriethoxysilane, ethyltriisopropoxysilane, octyltrimethoxysilane, octyltriethoxysilane, vinyltrimethoxysilane, vinyltriethoxysilane, phenyltrimethoxysilane, phenyltriethoxysilane, trimethoxysilane, triethoxysilane, triisopropoxysilane, fluorotrimethoxysilane, fluorotriethoxysilane, dimethyldimethoxysilane, dimethyldiethoxysilane, diethyldimethoxysilane, diethyldiethoxysilane, dimethoxysilane, diethoxysilane, difluorodimethoxysilane, difluorodiethoxysilane, trifluoromethyltrimethoxysilane, trifluoromethyltriethoxysilane, silicon carbide (SiC), other alkoxide organosilicon compounds {Si(OR)₄}, such as tetra-tertiary-butoxysilane {t-Si(OC₄H₉)₄} and tetra-secondary-butoxysilane {sec-Si(OC₄H₉)₄}, and polyalkylsiloxane containing an alkyl group, such as tetra-tertiary-amyloxysilane {Si [OC(CH₃)₂C₂H₅]₄}. To the above precursor material are added water and a catalyst while stirring at room temperature or at a higher temperature to promote the precursor to undergo a hydrolysis, forming a silicon hydroxide, and further the silicon hydroxide undergoes a condensation polymerization to form a low-molecular or high-molecular siloxane bond.

The silica particles 9 to be added have a particle diameter r of 5 to 50 nm. When the silica particles 9 have a particle diameter r of 5 nm or more, not only can aggregation of the silica particles 9 be suppressed, but also the specific surface area of the silica particles is reduced, so that a satisfactory amount of polysiloxane can be uniformly present on the surfaces of the particles. Therefore, the bond among the silica particles 9 becomes strong to suppress the formation of a crack in the film, enabling the film to maintain a high hardness. Further, when the silica particles 9 have a particle diameter r of 50 nm or less, in-plane unevenness of the thickness of the antireflection layer 4 can be reduced, making it possible to surely achieve stable transmission of light. The silica particles 9 may be either crystalline or amorphous. Further, the silica particles 9 may be either in the form of dry powder or in the form of a sol having the particles preliminarily dispersed in water or an organic solvent, but the silica particles in the form of a sol are preferably used because a glass paste can be easily prepared. When the silica particles 9 in the form of dry powder are used, a further step for dispersing the silica particles in a solvent is required. With respect to the method for producing the silica particles 9, there is no particular limitation, and the silica particles 9 may be produced by a fusion method, or produced in the form of dry powder by a combustion method, or produced by polymerization of water-glass or a sol-gel method. Further, with respect to the surface state of the silica particles 9, there is no particular limitation. In the step for adding the silica particles 9 to polysiloxane to prepare a paste material as a raw material for the antireflection film precursor 24, the silica particles 9 may be added either before or after a sol containing a siloxane bond is prepared, but it is necessary that the silica particles are satisfactorily dispersed. The amount of the added silica particles 9 is defined as a ratio of the silica particles to the siloxane bond finally remaining in the antireflection film 4, and the weight ratio of the silica particles 9 may be 10 to 99% by weight, preferably 50 to 99% by weight, with respect to the weight of the antireflection film 4. By using such materials, there can be formed the antireflection film 4 in which the silica:siloxane ratio is 80:20 to 95:5 as mentioned above.

It is desired that the paste material having a combination of the above materials has a viscosity of about 1 to 10 mPa·s at 100 [1/s] for facilitating the production. For achieving such a viscosity, the paste material desirably has a solids content (ratio of the total weight of the polysiloxane having a siloxane bond and the silica particles to the weight of the paste material) of 1 to 10% by weight, preferably 3 to 8% by weight.

Specifically, the raw material for the antireflection film having the above-mentioned combination is first applied to the light-transmitting member 5, followed by drying and firing, to form an antireflection film precursor 24 (FIG. 4A).

In the application of the raw material for the antireflection film, a slit coater method or a bar coater method is desirably used. The slit coater method is a method in which the paste material is discharged by pressure from a wide-mouthed nozzle to apply the paste material to a predetermined surface. The bar coater method is a method in which the paste material is discharged and then spread using a wire bar to apply the paste material to a predetermined surface. Alternatively, a spraying method may be used, but the spraying method has a disadvantage in that an ink is scattered over an undesired area to reduce the material utilization efficiency.

After the raw material for the antireflection film is applied, the raw material for the antireflection film is dried to remove the organic solvent. For surely forming the voids 8 and reducing the production time, the drying for removing the organic solvent is preferably thermal drying at 50 to 300° C. Alternatively, there may be employed, e.g., a vacuum drying method in which the evaporation of the solvent can be promoted by maintaining the degree of vacuum at the saturated vapor pressure of the solvent or less.

As shown in FIG. 4B, a first antireflection film 4a is formed through the above-mentioned drying step, and desirably has a thickness of 100 to 200 nm. When the first antireflection film 4a has a thickness of 100 nm or more, the light-transmitting member 5 is prevented from being heated by the thermal drying, making it possible to suppress the diffusion of alkali ions contained in the light-transmitting member 5 through the surface layer of the light-transmitting member. Further, when the first antireflection film 4a has a thickness of 200 nm or less, the transmission of a ray of light in a satisfactory amount can be surely achieved to obtain desired optical properties, and further in-plane unevenness of the light transmission caused due to the in-plane unevenness of the thickness of the first antireflection film can be reduced. In the antireflection film in the embodiment, the silica particles 9 have a particle diameter of about 5 to 50 nm, and therefore it is possible to control the antireflection film to have a thickness of 100 nm.

Next, as shown in FIG. 4C, the silica particles 9 present in the surface layer portion of the first antireflection film 4a are rapidly fused using a heat source 17 to form a second antireflection film 4b in the surface layer portion of the first antireflection film 4a, in which the silica particles are fused to reduce the voids 8. By employing such a method, H₂O and CO₂ are prevented from permeating through the antireflection film, so that diffused Na⁺ ions and diffused Ca²⁺ ions present on the surface of the light-transmitting member 5 can be prevented from reacting with H₂O and CO₂ in air. Further, the lowering of the light transmission when stored for a long term can be suppressed.

The rapid heat treatment for the first antireflection film 4a is conducted by a plasma torch annealing (PTA) method or the like. The PTA method is a method in which a plasma jet at a high speed and at a temperature as high as 10,000° C. or more is generated between an anode and a cathode by direct current arc discharge and optionally powder of a ceramic, cermet, or the like is placed in the plasma jet to accelerate the fusion, forming a film. In the PTA method, the heat capacity applied to the silica particles 9 present on the surface of the film can be changed by appropriately selecting conditions, such as the scanning speed, the gap between the film and the heat source, the scanning number, or the power of the heat source, thus controlling the thickness of the second antireflection film 4b and the arithmetic mean roughness Ra of the surface of the second antireflection film 4b. Further, for improving the in-plane uniformity of the thickness of the second antireflection film 4b having the silica particles 9 fused therein and reducing the treatment time so as not to form a seam in the treated film, it is desired that the rapid heat treatment is conducted using a plasma jet outlet of a long length.

When the thickness of the second antireflection film 4b, which is formed by fusing the silica particles 9 present on the surface of the dried first antireflection film 4a as mentioned above, is more than 10% of the thickness of the whole of the antireflection film, only a small antireflection effect can be obtained. Rays of sunlight include a ray of light having a wavelength in the range of 300 nm or more, and therefore, when the thickness of the silica particle fused solid layer having fused silica and no voids and having a high refractive index is reduced to 1/10 or less of the wavelength/refractive index, namely, 10% or less of the thickness of the whole of the antireflection film, the reflection of light off the surface of the antireflection film is reduced, so that a satisfactory antireflection effect can be obtained.

Further, it is desired that the surface of the second antireflection film 4b, which is formed by fusing the silica particles 9 present on the surface of the fired first antireflection film 4a as mentioned above, has an arithmetic mean roughness Ra of 2.5 nm or less. When the arithmetic mean roughness Ra of the surface of the second antireflection film 4b is more than 2.5 nm, the voids 8 are very likely to remain among the silica particles 9 in the surface layer of the second antireflection film 4b, that is, diffused Na⁺ ions and diffused Ca²⁺ ions cannot be prevented from reacting with H₂O or CO₂ in air. Therefore, the arithmetic mean roughness Ra of the surface of the second antireflection film 4b is 2.5 nm or less, and the voids 8 are satisfactorily reduced so that diffused Na⁺ ions and diffused Ca²⁺ ions are prevented from reacting with H₂O or CO₂ in air, thus suppressing the lowering of the light transmission when stored for a long term. As a result, a solar cell module having high long-term reliability can be formed.

The heat source used for the rapid heat treatment has high thermal response such that the silica particles 9 present in the surface layer of the first antireflection film 4a can be fused by irradiation with heat by the source for a short time, and is unlikely to cause thermal conduction up to the surface of the light-transmitting member 5. A similar result can be obtained using a flashlamp, a laser, or the like, which can prevent the Na⁺ ions and Ca²⁺ ions contained in the glass substrate from diffusing due to heating of the surface of the glass substrate.

### INDUSTRIAL APPLICABILITY

The solar cell module of the embodiment is advantageous not only in that rays of light in a satisfactory amount surely enter the solar cells, but also in that the deterioration of the antireflection film in reflectance can be suppressed to surely achieve excellent durability. The embodiment can be advantageously used in a method for producing a solar cell module comprising a plurality of solar cells each having an antireflection film, the solar cell module, and the like.

What is claimed is:

1. A solar cell module comprising:
a plurality of solar cells, and
a connector operable to electrically connect adjacent solar cells in the plurality of solar cells to each other,
the solar cell module having:
a light-transmitting member disposed to cover a light receiving surface of the solar cell module, and containing an alkali element,
a first antireflection film formed on the light-transmitting member, and comprising silica, a siloxane, and voids of the silica, and
a second antireflection film formed on the surface of the first antireflection film, and comprising the silica and the siloxane,
wherein the silica has a particle diameter of 5 nm to 50 nm.

2. The solar cell module according to claim 1, wherein a content ratio of the silica to the siloxane (silica:siloxane ratio) is 80:20 to 95:5.

3. The solar cell module according to claim 1, wherein a thickness of the second antireflection film is 10% or less of a total thickness of the first antireflection film and the second antireflection film.

4. The solar cell module according to claim 1, wherein a void ratio at an interface between the first antireflection film and the light-transmitting member is larger than a void ratio at an interface between the first antireflection film and the second antireflection film.

5. The solar cell module according to claim 1, wherein the second antireflection film includes the voids, wherein a void ratio of the second antireflection film is smaller than a void ratio at an interface between the first antireflection film and the second antireflection film.

6. The solar cell module according to claim 1, wherein when an average refractive index of the first antireflection film and the second antireflection film is taken as n, a total thickness of the first antireflection film and the second antireflection film is taken as d, and an average wavelength of rays of light incident on the solar cells is taken as λ, a relationship: 2nd=λ/2 is satisfied.

7. The solar cell module according to claim 1, wherein a total thickness of the first antireflection film and the second antireflection film is 100 nm to 200 nm.

8. The solar cell module according to claim 1, wherein the second antireflection film has a surface roughness of 2.5 nm or less.

9. The solar cell module according to claim 1, wherein each of the first antireflection film and the second antireflection film has a siloxane bond.

10. A method for producing a solar cell module comprising:
forming a light-transmitting member containing an alkali element on light receiving surfaces of a plurality of solar cells;
subjecting a mixture of polysiloxane, silica particles, and an organic solvent to drying and firing to form an antireflection film precursor on the light-transmitting member;
subjecting the antireflection film precursor to thermal drying to form a first antireflection film comprising silica, a siloxane, and voids of the silica; and
subjecting a surface of the first antireflection film to rapid heat treatment so that the silica particles are fused to form a second antireflection film containing the silica and the siloxane,
wherein the silica has a particle diameter of 5 nm to 50 nm.

11. The method for producing a solar cell module according to claim 10, wherein the rapid heat treatment is conducted by a plasma torch method or a heat treatment using a laser or a flashlamp.

12. The method for producing a solar cell module according to claim 10, wherein a content ratio of the silica to the siloxane (silica:siloxane ratio) is 80:20 to 95:5.

13. The method for producing a solar cell module according to claim 10, wherein a thickness of the second antireflection film is 10% or less of a total thickness of the first antireflection film and the second antireflection film.

14. The method for producing a solar cell module according to claim 10, wherein a void ratio at an interface between the first antireflection film and the light-transmitting member is larger than a void ratio at an interface between the first antireflection film and the second antireflection film.

15. The method for producing a solar cell module according to claim 10, wherein the voids are formed in the second antireflection film, wherein a void ratio of the second antireflection film is smaller than a void ratio at an interface between the first antireflection film and the second antireflection film.

16. The method for producing a solar cell module according to claim 10, wherein when an average refractive index of the first antireflection film and the second antireflection film is taken as n, a total thickness of the first antireflection film and the second antireflection film is taken as d, and an average wavelength of rays of light incident on the solar cells is taken as λ, a relationship: 2nd=λ/2 is satisfied.

17. The method for producing a solar cell module according to claim 10, wherein a total thickness of the first antireflection film and the second antireflection film is 100 nm to 200 nm.

18. The method for producing a solar cell module according to claim 10, wherein the second antireflection film has a surface roughness of 2.5 nm or less.

19. The method for producing a solar cell module according to claim 10, wherein each of the first antireflection film and the second antireflection film has a siloxane bond.

20. A solar cell module comprising:
a solar cell;
a light receiving surface disposed to receive incident light rays;
a light-transmitting member disposed to cover the light receiving surface and containing an alkali element;
a first antireflection film formed on the light-transmitting member, and comprising silica, a siloxane, and voids of the silica; and
a second antireflection film formed on the surface of the first antireflection film, and comprising the silica and the siloxane;
wherein the silica has a particle diameter of 5 nm to 50 nm.
